(19) United States
(12) Patent Application Publication
(10) Pub. No.: US 2005/0060884 A1
(43) Pub. Date: Mar. 24, 2005

(54) Fabrication of nanoscale thermoelectric devices

(75) Inventors: Yoshimasa Okamura, Sunnyvale, CA (US); Timothy L. Kohler, San Jose, CA (US); Mamoru Miyawaki, Cupertino, CA (US)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA

(21) Appl. No.: 10/666,787

(22) Filed: Sep. 19, 2003

(51) Int. Cl. H05K 3/02; H05K 3/20

(52) U.S. Cl. 29/846; 29/831; 29/868; 977/DIG. 1

(57) ABSTRACT

The present invention concerns a method for fabricating a nanowire thermoelectric device comprising the step of providing a substrate upon which to form nanowires. The substrate comprises substrate electrodes passing from a top exposed surface of the substrate to a bottom exposed surface of the substrate. Another step involves forming a first electrode pattern, which forms first and second electrically connected groups of substrate electrodes, on the bottom surface of the substrate. A p-type nanowire is then formed on the substrate by activating the first group of substrate electrodes during p-type material deposition. Similarly, a n-type nanowire is formed by activating the second group of substrate electrodes during n-type material deposition. And top electrodes are formed to connect the p-type and the n-type nanowires and a second electrode pattern is formed on the bottom side of the substrate to replace the first electrode pattern to form a thermocouple.

### BACKGROUND AND SUMMARY

1. Field of the Invention

The present invention generally relates to a method for fabricating nanowire thermoelectric devices.

2. Description of the Related Art

Nanowires are known in the art as wire structures which have a diameter measured in hundreds of nanometers (nm) or less, typically measured from 1 to 500 nm. When devices are constructed using structures of such a small scale, quantum mechanical rules and phenomena begin to have a greater effect on the operation of such devices in comparison to larger scale structures. The increased role and effect of quantum mechanics is due to the reduced number of atoms and electrons present in the system, which makes their discrete quantum natures more apparent.

While it is not known how quantum mechanics will affect the operation of all nanoscale devices, it has been found that thermoelectric modules (TEMs) constructed using nanowires are likely to show increased efficiency relative to even microsized TEM devices made with bulk materials.

The basic unit of a thermoelectric module is the thermocouple, which is typically made of two different materials, a p-type thermoelement and a n-type thermoelement, connected to each other at a high temperature side and a low temperature side. P-type thermoelements, made from p-type materials, transport charge through holes, where electrons are missing. N-type thermoelements, made from n-type materials, transport charge with electrons which travel through the material.

At the high temperature side and the low temperature side, electrodes (p-n connection electrode) may be provided to connect the two thermoelements. If appropriate materials are chosen for the thermoelements, applying a temperature difference between the two sides develops an electric current at the p-n connection electrodes and, conversely, applying a current to one of the p-n connection electrodes results in a temperature difference between the two sides. Thus, a thermoelectric module may function as either an electric generator or a cooling device.

It is known in the art that the amount of electric current produced by a thermocouple is proportional to the difference in temperature between the two sides of the thermocouple. This phenomena is known as the Seebeck effect, wherein heat energy is converted into electrical energy. Consequently, the Seebeck effect has been identified as a tool for recovering excess or waste heat energy.

The ability of a thermocouple to transfer heat with the application of an electric current is known as the Peltier effect. The amount of heat a thermocouple will transfer depends in part on the magnitude of the current applied. This effect has been employed to provide refrigerators and circuit cooling devices with no mechanical parts.

Another determining factor in the ability of a thermocouple to either absorb heat or produce electricity is the materials used in the p-type and n-type thermoelements. The thermoelectric property of a material is measured in terms of a dimensionless figure of merit (ZT). ZT is defined as follows:
ZT=(S²σ/κ)T
where S is the material's Seebeck coefficient, σ is a measure of the material's electrical conductivity, κ is a measure of the material's thermal conductivity, and T is the temperature.

As is apparent from the definition of ZT, desirable thermoelectric materials have high electrical conductivity, yet low thermal conductivity. Early research in the area of thermoelectrics focused on the use of metals as thermoelements. However, since the relationship between electrical conductivity and thermal conductivity for metals is fixed, the research yielded limited success. Consequently, attention was shifted to develop the use of semiconductors in thermoelectric modules, since semiconductors are capable of both high electrical conductivity and low thermal conductivity.

As noted above, it has been suggested that thermoelectric modules be constructed using nanowires since some studies have indicated that quantum effects enhance thermoelectric effects. Nanowire thermoelectric modules are envisioned as arrays of nanowires, where p-type and n-type nanowires alternate spatially and are close in proximity to each other so that they may be coupled together. Ideally, all the wires are packed tightly together to increase the number of thermocouples within a thermoelectric module in relation to the size of the module. Significant efforts are now being directed towards the development of such thermoelectric modules.

However, nanoscale elements are not easily produced by conventional methods. In addition since generation of electricity normally entails a large temperature gradient between the two sides of thermocouples, it is preferred that the thermoelements be as long as possible to increase the distance between the two sides. This is difficult for nanowires and their small diameters because increased length would increase the fragility of the nanowires. Conventional methods typically would not meet tolerances required for the production of nanowire thermoelectric modules and would likely damage their fragile structures.

### SUMMARY OF THE INVENTION

The present invention relates to methods for fabricating nanowire thermoelectric devices. In one aspect, the present invention provides a method for fabricating a nanowire thermoelectric device including the step of providing a substrate upon which to form nanowires, wherein the substrate comprises substrate electrodes passing from a top exposed surface of the substrate to a bottom exposed surface of the substrate. Also, included is the step of forming a first electrode pattern on the bottom exposed surface of the substrate, wherein the first electrode pattern forms first and second electrically connected groups of substrate electrodes.

The first and second electrically connected groups allow for the selective formation of nanowires. A p-type nanowire is formed on the substrate by activating the one of the electrically connected groups of substrate electrodes during p-type material deposition. Similarly, an n-type nanowire is formed on the substrate by activating at least one other electrically connected group of substrate electrodes during the n-type material deposition. Preferably, the p-type nanowires and n-type nanowires are formed by electrochemical deposition.

One side of the thermoelectric module is formed by forming top electrodes to connect the p-type nanowire to the n-type nanowire. The other side of the thermoelectric module is formed by forming a second electrode pattern on the bottom side of the substrate to replace the first electrode pattern such that a thermocouple is formed.

Because the substrate electrodes pass through substrate, access to the substrate electrodes is facilitated during patterning of the second electrode pattern. Due to this aspect of the invention, removal of a bottom substrate is ordinarily not needed to gain access to the bottom electrodes for repatterning after nanowire formation. As noted above, nanostructures tend to be fragile and any physical impact, by methods such as grinding or shaving, may cause damage to the nanowires.

Because the substrate remains substantially intact after nanowire formation, the substrate may act as a support structure and as a buffer between any activity that occurs on the bottom side of the substrate and the nanowires.

Additionally, because the first electrode pattern is formed on the substrate, the substrate electrodes may be selectively activated during nanowire formation, allowing for selective growth of nanowire materials. For example, in the process of growing the p-type nanowires, the substrate may be immersed in a p-type material deposition bath and the first electrically connected group of substrate electrodes is activated, which allows the p-type materials to be deposited on the substrate. The n-type nanowires may be grown by using a n-type material deposition bath and activating the second electrically connected group of substrate electrodes.

The substrate with through-electrodes, described above may be provided by depositing a conductive layer on a temporary substrate material such as glass, sapphire or silicon, and selectively removing areas of the conductive layer to leave electrode pads. Then, substrate materials are disposed around and on top of the electrode pads. Excess substrate material above the electrode pads and the temporary substrate are then removed, leaving the desired substrate with through-electrodes.

In forming the first electrode pattern on the bottom exposed surface of the substrate, a plurality of electrically connected groups of substrate electrodes is formed. It is preferable to form at least two groups of electrically connected substrate electrodes, a first and a second electrically connected group. Once again, since the first electrode pattern is on the exposed bottom surface of the substrate, the first and second electrically connected group can be more easily accessed for activation.

One way to form the first electrode pattern mentioned above is to deposit a conductive layer over the entirety of the bottom surface of the substrate. In this aspect, the electrode layer connects all electrodes and then is etched to form the first electrode pattern.

P-type nanowires are then formed by activating at least one electrically connected group during p-type material deposition. N-type nanowires are formed by activating at least one other electrically connected group during n-type material deposition. Thus, with the proper patterning of the first electrode pattern, n-type nanowires can be interspersed among the p-type nanowires.

To form the p-type nanowires and the n-type nanowires on the substrate, nanowires may be grown within nanopores. In one aspect of the present invention, a nanopore formation layer is disposed on the substrate, wherein the nanopore formation layer is a layer made of a material or materials in which nanopores are thereafter formed. The formation of nanopores in the nanopore formation layer is preferably carried out such that the nanopores are spaced evenly and each pore registers to at least one substrate electrode. Preferably, aluminum is used as the nanopore formation layer material. When aluminum is used as the nanopore formation layer, nanopores may be formed in the aluminum layer by anodic oxidation or other known methods. More preferably, nanopores are formed using ion implantation in combination with anodic oxidation to achieve good spacing of the nanopores and to achieve good alignment of the nanopores with the substrate electrodes.

Although, selective activation of the electrically connected groups of substrate electrodes should be sufficient to ensure the proper materials are grown in the proper nanopores, it is possible to use photoresist materials as added insurance. As p-type materials are being deposited in the desired nanopores, the nanopores wherein n-type materials will be later deposited may be covered by photoresist materials to prevent the infiltration of p-type materials. Similarly, nanopores wherein p-type materials are to be deposited may be covered by photoresist materials during n-type material deposition.

Other than electrical connections at the high temperature side and the low temperature side, the thermoelements should be electrically isolated from each other. Additionally, other than the connection provided by the thermoelements, the high temperature side of a thermocouple should be thermally isolated from its low temperature side. Thus, while removal of the nanopore formation layer is not necessary, removal of the nanopore formation layer after nanowire formation is preferred to achieve improved thermal isolation.

The removal of the nanopore formation layer can occur at anytime after the formation of the nanowires. However, it is preferred that the nanopore formation layer is not removed until absolutely necessary, since the layer will give structural support to the fragile nanowires throughout device fabrication.

Top electrodes are formed to connect the p-type nanowire and the n-type nanowire at their ends which do not contact the substrate electrodes. The top electrodes serve as one side of the thermocouple. Each top electrode should connect at least one p-type nanowire to at least one n-type nanowire. The resistance at the connection between the top electrodes and the nanowires is preferably as low as possible.

To form a thermocouple, a second side is provided and the p-type nanowire and the n-type nanowire are joined at another end. This may be accomplished by forming a second electrode pattern on the bottom side of the substrate. In this manner, the nanowires are connected at their top end by the top electrodes and are connected at their other end by their corresponding substrate electrodes and the second electrode pattern. The joined nanowires then form a complete thermocouple.

It is possible to achieve repatterning or replacement of the first electrode pattern to form the second electrode pattern by forming a second conducting layer on the bottom surface of the substrate over the first electrode pattern. In essence, the first electrode pattern becomes part of the second conducting layer. Preferably, the second conducting layer and the first electrode pattern consist of the same materials. Then, a second electrode pattern is formed using the second conducting layer. For example, the second conducting layer may be etched to form the second electrode pattern.

Where many thermocouples are formed on the same substrate, the second electrode pattern may be patterned so that the thermocouples are connected in series and/or in parallel to form an array of interconnected thermocouples. The combination of series and parallel connections can be modified to control the voltage and current output of the thermoelectric device. In this aspect of the invention, the second electrode pattern forms banks of series connected thermocouples and the banks are connected in parallel. Exactly how many thermocouples are in each bank and how many banks are connected in parallel depends upon the end use of the finished TEM. The second electrode pattern can be manipulated to produce a desired current or voltage. A general purpose optimization algorithm may be employed to determine a proper electrode pattern. Preferably, a genetic algorithm is used to generate the second electrode pattern to optimize the desired parameters.

After the array of thermocouples are formed, the array should be encapsulated. The resulting structure should have a first side corresponding to the high temperature side of the thermocouples contained therein and a second side corresponding to the low temperature side of the thermocouples contained therein. Also, included in the final device, there should be electrical leads connected to the electrodes contained within for the output or input of electricity.

Furthermore, after encapsulation, it is preferred to create a vacuum around the length of the nanowires to provide improved thermo-isolation between the high temperature side and the low temperature side.

The TEMs of the present invention can be fabricated to be electrical generating devices or cooling devices. Thus, TEMs of the present invention can take advantage of both the Seebeck effect and the Peltier effect. When used in electronic devices, they may be employed to cool electronic components or to recover energy lost as heat.

To enhance the operation of the TEMs, pyrolytic graphite sheets (PGSs) may be attached to the module to transfer heat as desired. PGSs, which are known to excellent heat conductors, may be attached to a TEM to transfer heat away from the lower temperature side of the TEM. Thus, the PGSs maintains or even enhances the temperature difference between the lower temperature side and the higher temperature side which is desirable for electric power generation. When attached to the higher temperature side, the PGS may serve to bring heat to the TEM from a distant source. As such the TEM is not necessarily placed in close proximity to the source of the heat to generate current.

This brief summary has been provided so that the nature of the invention may be understood quickly. A more complete understanding of the invention can be obtained by reference to the following detailed description of the preferred embodiment thereof in connection with the attached drawings.

### BRIEF DESCRIPTION OF THE DRAWINGS

FIG. 1 shows a cross section of the TEM fabricated by the method of present invention, including the substrate with through-electrodes.

FIGS. 2a through 2g show the various stages TEM fabrication according to one aspect of the present invention from a cross-sectional view.

FIGS. 3a through 3c shows one method of providing the substrate with through electrodes used in the present invention.

FIGS. 4a through 4c show exemplary bottom views of the substrate with through electrodes used in the present invention during select stages of TEM fabrication.

FIG. 5 shows a top view of the placement of the top electrodes which corresponds to the bottom view shown in FIG. 4c.

### DETAILED DESCRIPTION OF THE INVENTION

The present invention provides a method for fabricating a nanoscale thermoelectric module, wherein the thermoelements are nanowire structures. The TEM produced is expected to have more efficient thermoelectric qualities due to the nanowire thermoelements. Furthermore, the fabrication method that is provided is likely to yield numerous advantages, such as a decreased likelihood of damage to the nanowires during device fabrication, adaptability to automation and lower manufacturing costs.

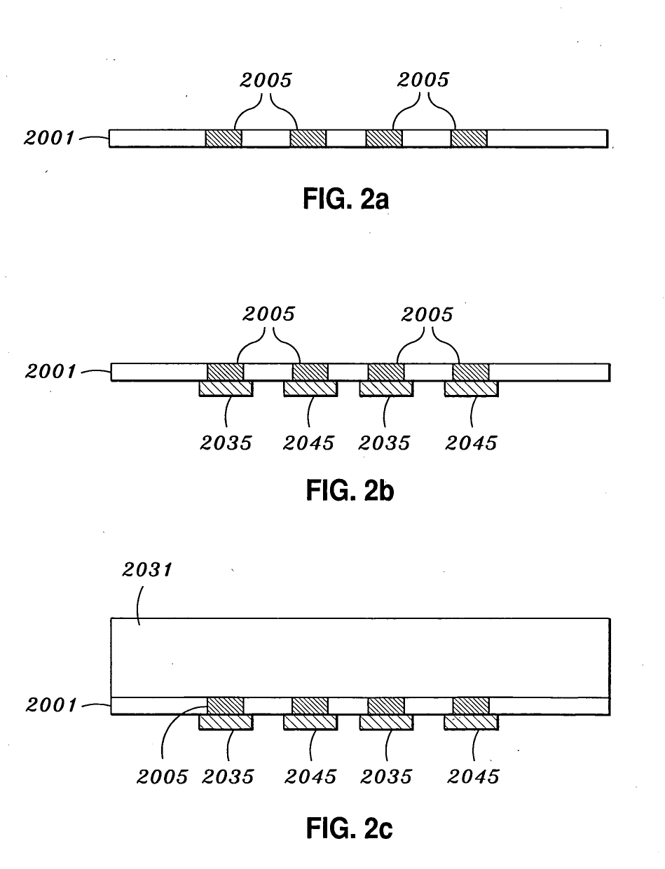

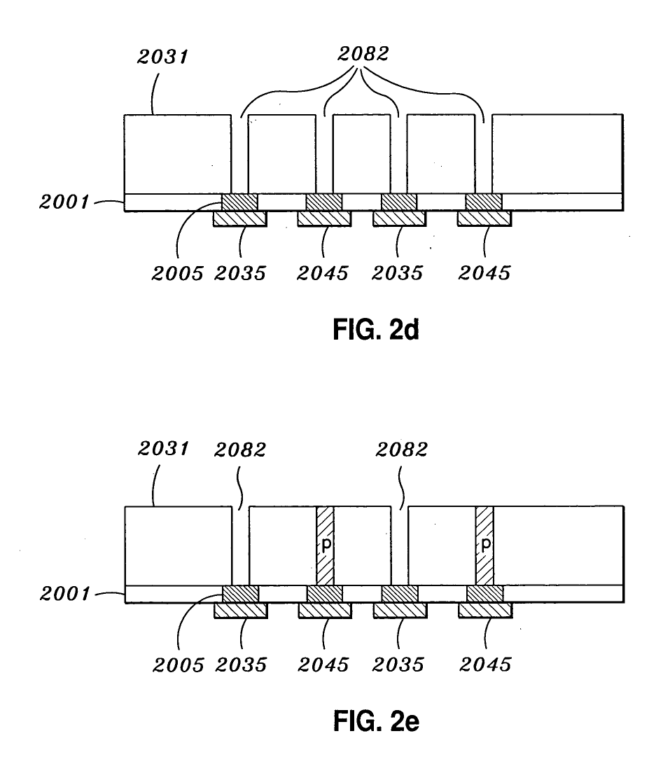

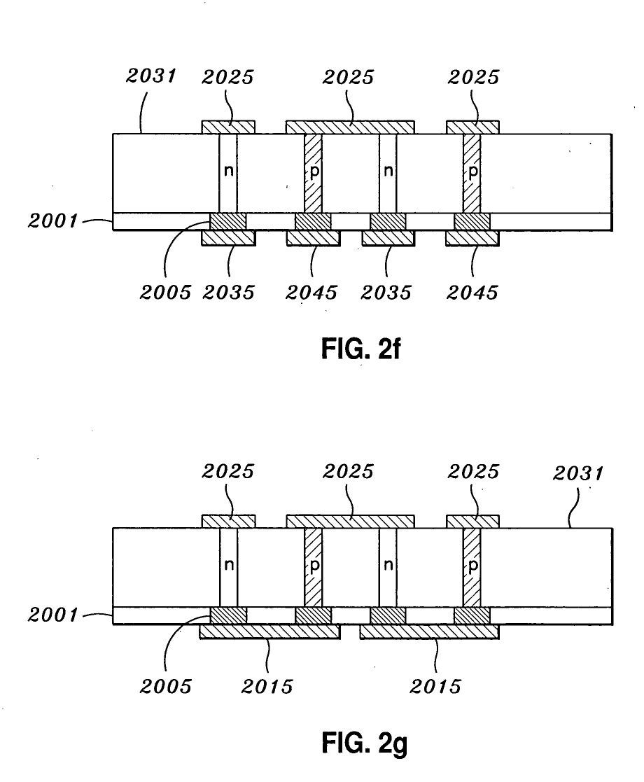

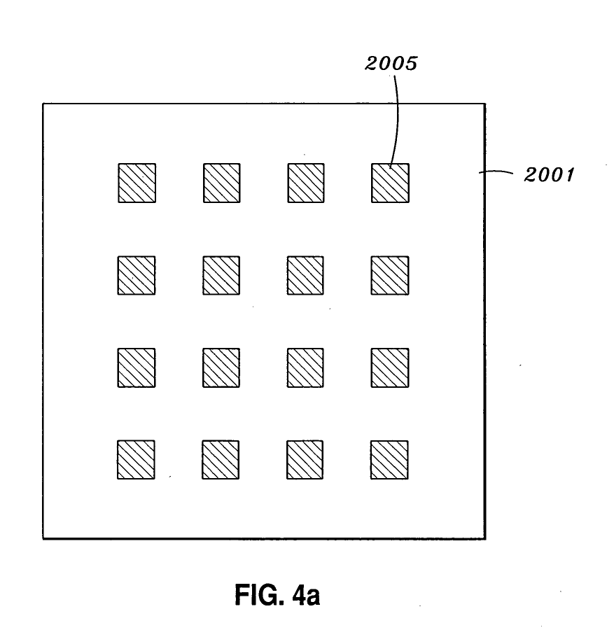

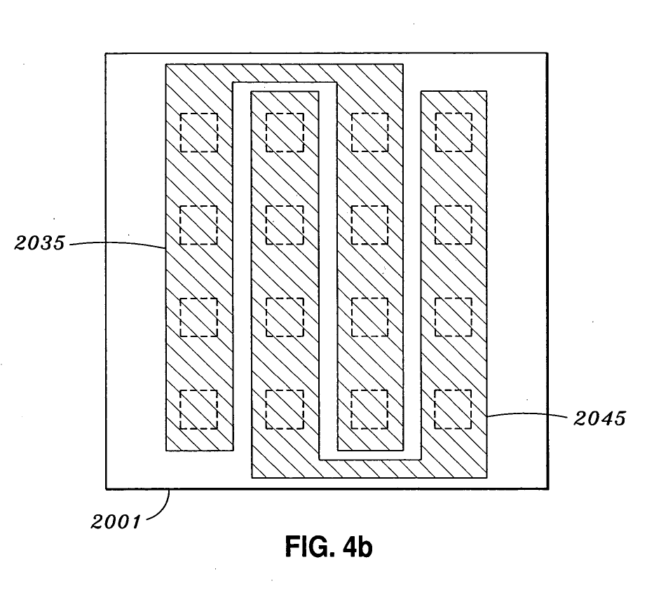

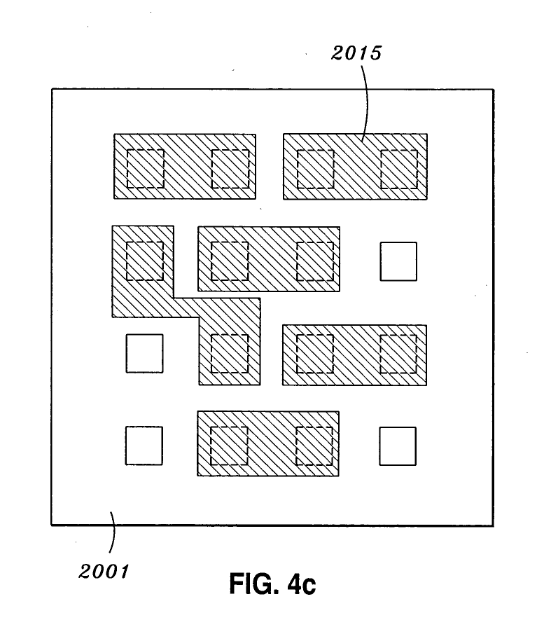

FIGS. 2a through 2g show various stages of one embodiment of the method of the present invention from a cross-sectional view. FIGS. 4a to 4c show a bottom view of select stages of TEM fabrication.

One feature of the present invention is the use of a substrate with through-electrodes upon which the p-type and n-type nanowires are to be grown, an example of which is shown in FIG. 2a. FIG. 4a shows the bottom view of the substrate shown in FIG. 2a. The substrate (2001) has substrate electrodes (2005) embedded within it, wherein the electrodes may be electrically contacted from both the top surface of the substrate and also the bottom surface of the substrate. Thus, the substrate has electrodes passing from the top exposed surface to the bottom exposed surface.

The use of a substrate with through-electrodes provides a degree of protection for the nanowires which are to be formed on the substrate. Because the substrate has electrodes which are accessible from both the top and bottom surface, electrode patterns can be patterned and repatterned on the bottom surface, as discussed below, without containing nanowires which may connected on the top surface. If the electrode patterns were to sit on the top surface of the substrate, once nanowires are formed on the electrode pattern the substrate must ordinarily be removed to affect a change in the electrode pattern. Removal of the substrate is not ordinarily necessary according to the present invention.

Furthermore, if mechanical processes are employed to remove the substrate, such as grinding or shaving, the nanowires might be damaged in the process. This is especially a concern since little tolerance is available when working on a nanoscale devices. The present invention allows for the formation of a TEM without the use of mechanical processes to remove the substrate.

On the other hand, if a mechanical process to form or repattern the electrode patterned on the bottom surface is desired for some other reason, the presence of the substrate between the electrode pattern and the nanowires may serve to shield the nanowires from physical impact.

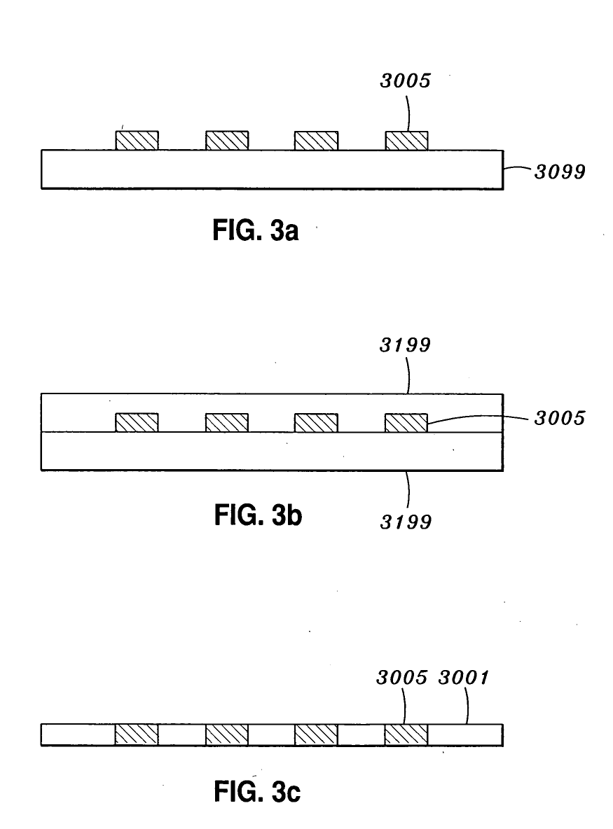

One possible technique for providing the above-mentioned substrate with through-electrodes is shown in FIGS. 3a through FIGS. 3c. A temporary substrate (3099) is provided upon which electrode pads (3005) are deposited. While other methods are available, depositing the electrode pads is preferably achieved by lithography. Because the electrode pads are to later serve as the substrate electrodes mentioned above, their precise placement using the most accurate techniques is preferred. Any material which has electrical conductivity may be used as the electrode material. However, gold is preferred. The electrode pads are then surrounded and covered by a substrate material (3199). Preferably, the substrate material is an insulating material, such as amorphous SiO₂, since this material will compose the substance of the resulting substrate with through-electrodes. Other suitable materials for the substrate include glass, sapphire and silicon. Once the substrate material is in place, the excess material over the electrode pads (3005) is removed to expose the electrodes, while the material surrounding the electrodes is left in place. The temporary substrate (3099) is also removed to yield the desired substrate electrodes with through-electrodes (3001).

Once the substrate is provided, an electrode pattern is patterned on the bottom surface, as shown in FIG. 2b. This pattern will herein be referred to as the first electrode pattern. The first electrode pattern may be provided by plating the bottom side of the substrate with an electrode material, referred to herein as a first conducting layer, and then etching the first conducting layer to provide the desired pattern. FIG. 4b shows what the first electrode pattern may look like from a bottom view of the substrate (2001).

The first electrode pattern serves to electrically connect substrate electrodes. Substrate electrodes are grouped together for selective nanowire growth, as will be discussed below, and are connected in such a manner as to provide a plurality of groups of electrically connected electrodes. As shown in FIG. 4b, two electrically connected groups are formed by patterned electrodes (2035 and 2045) formed by the first electrode pattern. Substrate electrodes which are in the same group can be activated together. Consequently, the first electrode pattern allows for selective activation of substrate electrodes and, ultimately, the selective formation of p-type nanowires and n-type nanowires.

The nanowires used in the present invention may be acquired a number of ways. One method used in the present invention involves forming the nanowires within a nanopore. While it is possible to use a template with nanopores preformed, it is preferred that nanopores are formed after a nanopore formation layer is disposed on the substrate with through-electrodes. FIG. 2c. shows a substrate with a nanopore formation layer (2031) disposed on the top surface and in contact with the substrate electrodes (2005). Preferably, the nanopore formation layer covers the entire surface of the substrate, and is of a material which is appropriate for nanopore formation. As for the thickness of the formation layer, it may vary. However, since the thickness of the layer plays a part in determining the length of the nanowires formed, the thickness of the layer should be chosen according to the desired length of the nanowires.

Nanopores (2082) are formed in the nanopore formation layer (2031) in a manner that each pore registers with at least one substrate electrode (2005), as shown in FIG. 2d. Also, each substrate electrode (2005) preferably connects to only one nanopore (2082).

A preferred method of forming the nanopores is through anodic oxidation. In this aspect of the invention, any material which is suitable for anodic oxidation may be used as the nanopore formation layer, although aluminum is preferred. More preferably, anodic oxidation is used in combination with ion beam implantation, which seeds the nanopore formation layer for nanopore formation. Ion beam implantation may allow for superior spacing and may provide for nanopores which register well with the substrate electrodes.

The nanopores of the present invention have a diameter of 5 nm to 500 nm and a depth of 1 μm to 500 μm. Preferably, the nanopores have a diameter of 5 nm to 100 nm. More preferably, the nanopores have a diameter of 10 nm to 50 nm. Furthermore, the nanopores should be spaced from 50 μm to 1 μm from each other. Preferably, the nanopores have a 200 nm pitch.

After the nanopore formation layer is disposed on the substrate and nanopores are provided, the present invention employs the first electrode pattern described above to selectively form p-type and n-type nanowires. Accordingly, the present invention allows for the formation of p-type nanowires interspersed among n-type nanowires and vice versa. This may be achieved by activating at least one group of electrically connected electrodes during p-type nanowire formation and activating at least one other group of electrically connected electrodes during n-type nanowire formation. Preferably, electrochemical deposition is used to form the nanowires

Thus, when electrochemical deposition is used to provide nanowire formation, at least two different material baths are employed. For p-type nanowire formation, a p-type material bath is employed. During the p-type material bath, at least one group of electrically connected electrodes is activated, for example the group connected to the pattern electrode (2045). Thus, p-type nanowires are formed in select nanopores, while non-selected nanopores remain empty. FIG. 2e shows the result of p-type nanowire formation. As shown, p-type nanowires are formed only in nanopores corresponding to the electrodes connected by pattern electrode (2045).

In the n-type bath, at least one other group of electrically connected electrodes are activated, for example the group connected by the pattern electrode (2035). Accordingly, n-type nanowires are formed in the appropriate nanopores.

Another technique which allows for selective growth of nanowires is to use photoresist to cover nanopores wherein deposition is not desired. For example, during p-type material deposition or formation, nanopores in which n-type nanowires are to be grown may be covered with photoresist to prevent the deposition or formation of p-type materials in that nanopore. Conversely, photoresist may be used to cover or block the deposition or formation of n-type materials in the nanopores meant for p-type materials.

Using the method described above, an array of p-type and n-type nanowires can be formed. The nanowires formed in the present invention have a diameter of 5 nm to 500 nm and a length of 1 μm to 500 μm. Preferably, the nanowires have a diameter of 5 nm to 100 nm. More preferably, the nanowires have a diameter of 10 nm to 50 nm. Furthermore, the nanowires should be spaced from 50 nm to 1 μm from each other. Preferably, the nanowires have a 200 nm pitch.

Once the nanowires have been formed, the nanopore formation layer may be removed. Removal is preferred if the formation layer has high heat conductive properties or high electrical conductive properties. However, removal of the formation layer is not required.

If the nanopore formation layer is removed, then ideally the layer is not removed until absolutely necessary because the formation layer may provide structural support to the nanowires throughout device fabrication. By leaving the formation layer intact throughout device fabrication, the nanowires remain encased and are somewhat protected from movement and impact. On the other hand, once the nanowire formation layer is removed, the nanowires are left substantially free standing and may break or bend.

Despite that it is preferable to keep the nanopore formation layer in place as long as possible, it is also preferred that the nanopore formation layer eventually be removed prior to completion of the device. Thus, the space around the nanowires may be replaced with an insulating material, or more preferably a vacuum. An insulating material is preferred because it is desirable to keep the nanowires electrically isolated from each other, except for the electrodes provided, and it is desirable to keep their ends thermally isolated from each other. Furthermore, since a vacuum is seen to be the best insulator against heat and electrical conduction, a vacuum would be more preferred.

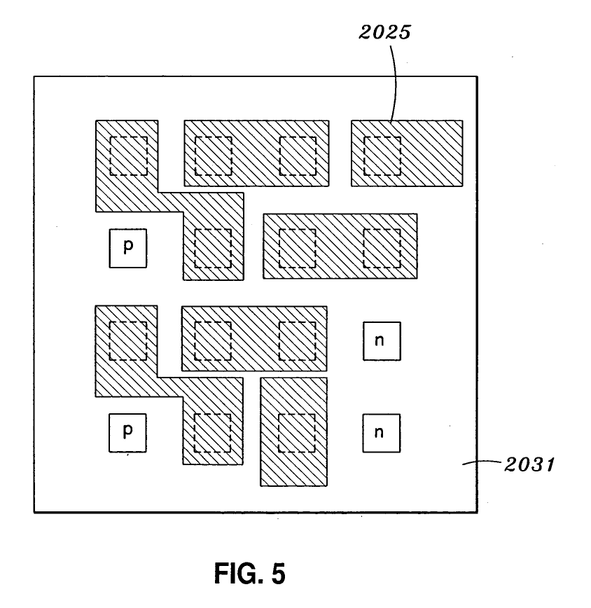

Another reason for leaving the nanopore formation layer in place until absolutely necessary is to allow for a surface on which to deposit the top electrodes. The top electrodes may serve to connect p-type nanowires and n-type nanowires at their ends which are furthest away from the substrate with through-electrodes. Alternatively, the top electrodes may serve as connection points for connecting a load or power source to the nanowires. For the purpose of connecting nanowires to each other, the top electrodes may contact more than one of each type of nanowire. However, it is preferred that each top electrode connects only one p-type nanowire and one n-type nanowire. FIG. 2f shows top electrodes (2025) deposited on the nanopore formation layer (2031). FIG. 5 shows how top electrodes (2025) might be placed on a nanopore formation layer (2031) after nanowires have been deposited from a top view of a TEM.

In regards to the placement of the top electrodes, they should be placed in a pattern which is complimentary to the final arrangement of the electrode pattern on the bottom surface of the substrate with through-electrodes. In other words, the top electrodes should be placed in a pattern which would not cause shorts or other undesirable affects when the electrode pattern on the bottom side of the TEM is finalized. The finalized electrode pattern on the bottom side of the TEM, referred to as the second electrode pattern herein, will be discussed more throughly below.

Since the first electrode pattern, which was used to selectively grow p-type and n-type nanowires, may be unsuitable for thermoelectric purposes, it may be desirable to replace that pattern with a second electrode pattern. The second electrode pattern should compliment the placement of the top electrodes in such a fashion as to form functional thermoelectric couples connected in series and/or in parallel. FIG. 2g. shows electrodes (2015) of the second electrode pattern have replaced the electrodes of the first electrode pattern (2035 and 2045 in FIGS. 2b through 2f). FIG. 4c shows, from a bottom view of the TEM, what a second electrode pattern, which corresponds to the placement of top electrodes (5025) shown in FIG. 5, might look like.

As shown in FIG. 4c and FIG. 5, not all nanowires are electrically connected to the top electrodes and second electrode pattern. In the present invention, it is not ordinarily necessary to connect all nanowires. In one aspect of the invention some nanowires may be left unconnected to insure that the p-type nanowires and the n-type nanowires are connected in an alternating pattern to allow a series connection. Alternatively, no nanowires may be formed at positions where they are not needed. To prevent nanowire formation, it is possible to prevent the formation of a nanopore at the position of interest by blocking the nanopore with a photoresist or photomask material.

However, connecting all nanowires is preferred and thus the placement of substrate electrodes, p-type and n-type nanowires and top electrodes as well as the formation of the second electrode pattern may be carefully planned to optimize the use of materials and space.

Also, FIG. 5 shows two electrodes which do not connect two nanowires and contact only one nanowire. These electrodes are meant to provide connection points for the system to a load or power source. These connection points may, alternatively, be provided with the electrodes on the bottom side.

Because the first electrode pattern is on the bottom side of the substrate with through-electrodes, it is possible to repattern the electrode pattern without contacting the nanowires on the upper side of the substrate. One technique for replacing the first electrode pattern with the second electrode pattern is to cover the first electrode pattern with an electrically conductive material, a second conductive layer. While any electrically conductive material is likely to suffice, preferably the conductive material is the same as the material used to form the first electrode pattern. Thus, the first electrode pattern becomes a part of the second conductive layer. Then, the second conductive layer may be etched to form the second electrode pattern.

Preferably, the second electrode pattern connects the array of nanowires to form thermocouples which are connected in series, parallel or both. By controlling the number of thermocouples connected in series and/or parallel, it is possible to control the output current and voltage of the resulting TEM device. Consequently, TEMs produced by the present invention may be designed to produce different current and voltage outputs and thus may be designed for specific needs.

In the present invention, since so many nanowires may be produced, it may be difficult to choose a second electrode pattern. This difficulty may be dealt with by applying any general purpose optimization algorithm or, preferably, a genetic algorithm to determine an appropriate pattern for the second electrode pattern.

Patterning of the second electrode pattern forms an array of thermocouples. To finish the basic TEM structure, the array may be encapsulated to give additional structure and support. The resulting capsule should have one surface which corresponds to the bottom side of the substrate with through-electrodes and a second surface which overlays the top electrodes. These two surfaces lie on opposite sides of the TEM. By applying a temperature difference between these two surfaces an electrical current is expected to be produced. By applying a current to the nanowires within the TEM, a temperature difference between the two surfaces is expected. Hence, the TEM will have a higher temperature side and a lower temperature side.

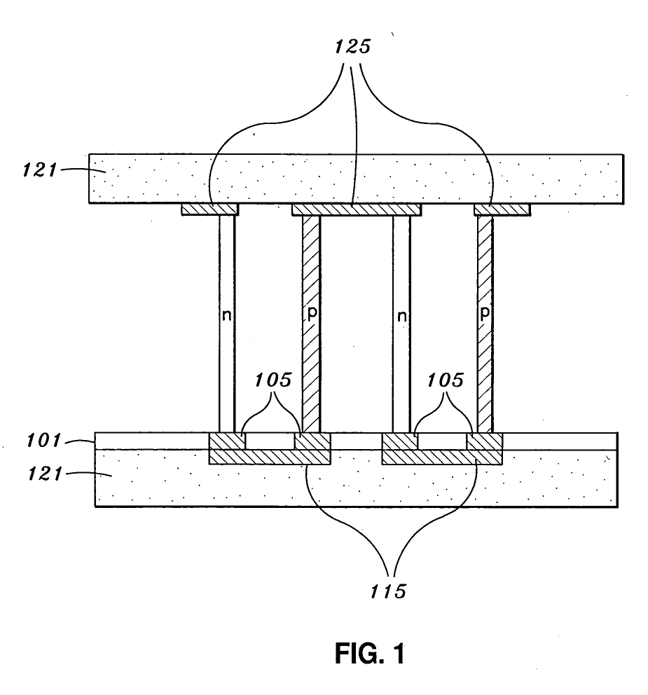

FIG. 1 shows a cross section of a TEM device produced by the present invention. As shown, the thermocouples comprised of p-type nanowires and n-type nanowires are connected in series. Top electrodes (125) and electrodes of the second electrode pattern (115) serve to electrically connect p-type nanowires to n-type nanowires. The nanowires are connected to the electrodes of the second electrode pattern (115) through the substrate electrodes (105), which pass through the substrate with through-electrodes (101). Also, a partial portion of the encapsulating structure (121) is shown.

An outer shell, produced by encapsulation, should be able to conduct heat to and away from the underlying electrodes and nanowires. Yet, at the same time, the outer shell should not allow for the conduction of heat from the higher temperature side to the lower temperature side, otherwise any applied temperature difference would be defeated.

There should be a means for electrically connecting the array of thermocouples to an outside load or power source. Thus, electrical leads may be provided that allow for electrical connectivity to the electrode patterns held within the TEM.

The resulting TEMs produced by the present invention may be used as power generators, cooling devices or both. As a power generator, the TEM may be placed near a heat source such that the high temperature side will receive heat. Due to the resulting temperature difference between the two sides of the TEM a current will be produced. One application for the TEMs produced by the present invention is to place them in or on electronic devices which produce waste heat to recover lost energy.

As discussed above, the operation of a TEM as a power generator is dependent upon the difference in temperature between the higher temperature side and the lower temperature side. To provide or enhance this temperature difference, pyrolytic graphite sheets (PGSs) may be used in combination with TEMs produced by the present invention. PGSs, which have excellent heat conducting properties, may be attached to the higher temperature side of a TEM to bring heat to the TEM. Consequently, through the use of PGSs, the TEM need not be placed close to a heat source to generate power. Alternatively, a PGS may be attached to the lower temperature side of a TEM to assist in the dissipation of heat and making the lower temperature side relatively cooler.

Alternatively, as cooling devices, the TEMs produced by the present invention would be placed near or on objects which need cooling and a current would be applied to the TEM to cool as necessary.

The present invention is defined by the claims and is understood to include such obvious variations and modifications as would be obvious to those of ordinary skill in the art.

1. A method for fabricating a nanowire thermoelectric device comprising the steps of:
providing a substrate upon which to form nanowires, wherein the substrate comprises substrate electrodes passing from a top exposed surface of the substrate to a bottom exposed surface of the substrate;
forming a first electrode pattern on the bottom surface of the substrate, wherein the first electrode pattern forms a plurality of electrically connected groups of substrate electrodes;
forming a p-type nanowire on the substrate by activating at least one electrically connected group of substrate electrodes;
forming a n-type nanowire on the substrate by activating at least one other electrically connected group of substrate electrodes;
forming top electrodes to connect the p-type nanowire and the n-type nanowire and forming a second electrode pattern on the bottom surface of the substrate to replace the first electrode pattern such that a thermocouple is formed.

2. The method for fabricating a nanowire thermoelectric device according to claim 1, wherein the substrate is provided by a method comprising the steps of:
depositing an electrode layer on a temporary substrate material;
selectively removing areas of the electrode layer to leave electrode pads;
depositing substrate materials around and on top of the electrode pads; and
removing the temporary substrate and the substrate material above the electrodes.

3. The method for fabricating a nanowire thermoelectric device according to claim 1, further comprising the steps of disposing a nanopore formation layer on the substrate and forming nanopores in the nanopore formation layer after the nanopore formation layer is disposed on the substrate.

4. The method for fabricating a nanowire thermoelectric device according to claim 3, wherein the nanopores in the nanopore formation layer are registered to the substrate electrodes.

5. The method for fabricating a nanowire thermoelectric device according to claim 3, wherein the nanopore formation layer comprises Al and anodic oxidation is used to create nanopores within the nanopore formation layer.

6. The method for fabricating a nanowire thermoelectric device according to claim 5, wherein the nanopore formation layer is removed prior to completion of the thermoelectric device.

7. The method for fabricating a nanowire thermoelectric device according to claim 6, where in the nanopore formation layer is not removed until after the second electrode pattern is formed.

8. The method for fabricating a nanowire thermoelectric device according to claim 1, wherein either the p-type nanowire or the n-type nanowire is formed prior to the formation of another type of nanowire.

9. The method for fabricating a nanowire thermoelectric device according to claim 1, wherein many thermocouples are formed and are connected in series and/or parallel by the second electrode pattern.

10. The method for fabricating a nanowire thermoelectric device according to claim 9, wherein the thermocouples form banks of series connected thermocouples and the banks of series connected thermocouples are connected in parallel.

11. The method for fabricating a nanowire thermoelectric device according to claim 9, further comprising the step of applying a general purpose optimization algorithm to determine a second electrode pattern which optimizes the connection of the many thermocouples.

12. The method for fabricating a nanowire thermoelectric device according to claim 9, further comprising the step of applying a genetic algorithm to determine a second electrode pattern which optimizes the connection of the many thermocouples.

13. The method for fabricating a nanowire thermoelectric device according to claim 1, wherein more than one p-type nanowire is formed; more than one n-type nanowire is formed; and more than one top electrode is formed,
wherein the top electrodes are formed to connect one of the p-type nanowires to one of the n-type nanowires.

14. The method for fabricating a nanowire thermoelectric device according to claim 1, further comprising the steps of:
forming a second conducting layer on the bottom surface of the substrate over the first electrode pattern; and
forming the second electrode pattern using the second conducting layer.

15. The method for fabricating a nanowire thermoelectric device according to claim 1, further comprising the steps of encapsulating the substrate and nanowire thermocouples to form a nanowire thermoelectric module and creating a vacuum around the nanowires.

16. The method for fabricating a nanowire thermoelectric device according to claim 1, further comprising the steps of encapsulating the substrate and nanowire thermocouples to form a nanowire thermoelectric module; and
attaching a pyrolitic sheet to the thermoelectric module.

17. The method for fabricating a nanowire thermoelectric device according to claim 1, wherein the p-type nanowires and n-type nanowires are formed by electrochemical deposition.

18. The method for fabricating a nanowire thermoelectric device according to claim 1, wherein the p-type nanowires and n-type nanowires formed have a diameter of 5 nm to 500 nm.

19. The method for fabricating a nanowire thermoelectric device according to claim 1, wherein the p-type nanowires and n-type nanowires formed have a diameter of 5 nm to 100 nm.

20. The method for fabricating a nanowire thermoelectric device according to claim 1, wherein the p-type nanowires and n-type nanowires formed have a diameter of 10 nm to 50 nm.

21. A method for fabricating a nanowire thermoelectric device comprising the steps of:
providing a substrate upon which to form nanowires, wherein the substrate comprises substrate electrodes passing from a top surface of the substrate to a bottom surface of the substrate, and wherein the substrate electrodes are electrically connected to each other by a first conducting layer disposed on the bottom surface of the substrate;
forming a first electrode pattern using the first conducting layer, wherein the first electrode pattern forms first and second electrically connected groups of substrate electrodes;
disposing a nanopore formation layer on the substrate within which nanopores may be formed;
forming nanopores within the nanopore formation layer after disposing the nanopore formation layer on the substrate, such that the nanopores are registered to the substrate electrodes;
forming a p-type nanowire in some of the nanopores by activating the first electrically connected group of substrate electrodes during a p-type material deposition;
forming a n-type nanowire in some of the nanopores by activating the second electrically connected group of substrate electrodes during n-type material deposition;
forming top electrodes on the nanopore formation layer to connect the p-type nanowire to the n-type nanowire;
replacing the first electrode pattern with a second electrode pattern on the bottom surface of the substrate to form nanowire thermocouples,
wherein the nanowire thermocouples form either a serial or a parallel connection or a combination of both; and
encapsulating the substrate and nanowire thermocouples to form a nanowire thermoelectric module.
